(19) United States
(12) Patent Application Publication
(10) Pub. No.: US 2025/0056854 A1
(43) Pub. Date: Feb. 13, 2025

(54) EPITAXIAL STRUCTURE OF SEMICONDUCTOR DEVICE, MANUFACTURING METHOD THEREOF, AND SEMICONDUCTOR DEVICE

(71) Applicant: DYNAX SEMICONDUCTOR, INC., Kunshan (CN)

(72) Inventors: Hui ZHANG, Kunshan (CN); Wenlong ZHOU, Kunshan (CN); Kewei TAN, Kunshan (CN); Xiaoqing DU, Kunshan (CN); Susu KONG, Kunshan (CN)

(21) Appl. No.: 18/719,449

(22) PCT Filed: Dec. 14, 2022
(86) PCT No.: PCT/CN2022/139012

§ 371 Date: Jun. 13, 2024

(30) Foreign Application Priority Data
Dec. 15, 2021 (CN) 202111535196.0

(51) Int. Cl. H01L 29/04; H01L 21/02

(52) U.S. Cl. CPC H01L 29/045; H01L 21/02609

(57) ABSTRACT

The disclosure discloses an epitaxial structure of a semiconductor device, as well as a manufacturing method thereof, and a semiconductor device. Therein, the epitaxial structure includes a substrate and an epitaxial layer located on one side of the substrate, and a surface roughness of one side the substrate close to the epitaxial layer is Ra, wherein 0<Ra≤5 nm. In the epitaxial structure of a semiconductor device as well as the manufacturing method thereof and the semiconductor device provided by the disclosure, by setting the surface roughness Ra on one side of the epitaxial growth of the substrate to satisfy 0<Ra≤5 nm, a high-quality epitaxial layer can be directly epitaxially grown on the substrate, eliminating the need to arrange a thicker buffer layer and thus reducing thermal resistance, which improves the operating performance of the semiconductor device.

### CROSS REFERENCE TO RELATED APPLICATIONS

This patent application is a National Stage Entry of PCT/CN2022/139012 filed on Dec. 14, 2022, which claims the benefit and priority of Chinese Patent Application No. 202111535196.0 filed on Dec. 15, 2021, the disclosures of which are incorporated by reference herein in their entirety as part of the present application.

### BACKGROUND

Embodiments of the present disclosure relate to the technical field of semiconductor, and particularly relate to an epitaxial structure of a semiconductor device, a manufacturing method thereof, and a semiconductor device.

The third-generation semiconductor material gallium nitride (GaN) has become a current research hotspot due to its characteristics such as large band gap, high electron saturation drift velocity, high breakdown field strength, and good thermal conductivity. In terms of electronic devices, gallium nitride materials are more suitable than silicon and gallium arsenide for manufacturing high-temperature, high-frequency, high-voltage, and high-power devices. Therefore, gallium nitride electronic devices have good application prospects in radio frequency microwave, power electronics, and other fields.

High Electron Mobility Transistor (HEMT) is a wide bandgap semiconductor device with high concentration of Two-Dimensional Electron Gas (2DEG), has the characteristics of high output power density, high temperature resistance, strong stability, and high breakdown voltage, and has great application potential in the field of power electronic devices.

As for GaN-based HEMT heterostructures used for high-frequency and high-power applications, epitaxial layers need to be epitaxially grown on the substrate. The existing epitaxial layers have problems with high thermal resistance, which greatly affects the operating performance of the semiconductor device.

### BRIEF DESCRIPTION

The disclosure provides an epitaxial structure of a semiconductor device, as well as a manufacturing method thereof, and a semiconductor device, to reduce thermal resistance and improve the operating performance of the semiconductor device.

In a first aspect, embodiments of the present disclosure provide an epitaxial structure of a semiconductor device, including:
a substrate; and
an epitaxial layer located on one side of the substrate;
wherein, a surface roughness of one side the substrate close to the epitaxial layer is Ra, wherein 0<Ra≤5 nm.

In one embodiment, 0.2 nm≤Ra≤5 nm.

The epitaxial layer may include a nucleation layer located on one side of the substrate and a channel layer located on one side of the nucleation layer away from the substrate; and
materials of the nucleation layer and the channel layer are both nitrides.

The epitaxial layer further may include a barrier layer, the barrier layer being located on one side of the channel layer away from the substrate; and
a thickness of the barrier layer is d1, and a distance between a surface of one side of the channel layer away from the substrate and a surface of one side of the substrate close to the channel layer is d2, wherein 3*d1≤d2≤30*d1.

A carrier layer may be formed in the epitaxial layer, and a distance between the carrier layer and the substrate may be d3, wherein d3≤600 nm.

A thickness of the nucleation layer may be d4, wherein 5 nm≤d4≤100 nm.

A thickness of the epitaxial layer may be d5, wherein d5≤1500 nm.

A surface crystal orientation of the substrate may be {0001}:
an angle at which surface orientation of the substrate deviates from a normal crystal orientation is α, wherein −0.25°<α>0.25°:
or,
an angle of the surface orientation of the substrate toward a <1120> direction is, wherein 3.5°−0.5°<β≤3.5°+0.5°, or 4°−0.5°<β≤4°+0.5°, or 8°−0.5°≤β≤8°+0.5°.

The epitaxial layer further may include a cap layer, the cap layer being located on one side of the barrier layer away from the substrate.

In a second aspect, embodiments of the present disclosure further provide a semiconductor device, including any epitaxial structure of a semiconductor device according to the first aspect.

In a third aspect, embodiments of the present disclosure further provide a method of manufacturing an epitaxial structure of a semiconductor device, for manufacturing any epitaxial structure of a semiconductor device according to the first aspect, the method including:
providing a substrate, a surface roughness of a first side of the substrate being Ra, wherein 0<Ra≤5 nm; and
forming an epitaxial layer on the first side of the substrate.

In the epitaxial structure of a semiconductor device as well as the manufacturing method thereof and the semiconductor device provided by embodiments of the present disclosure, by setting the surface roughness Ra on one side of the epitaxial growth of the substrate to satisfy 0<Ra≤5 nm, a high-quality epitaxial layer can be epitaxially grown on the substrate, thereby eliminating the need to form a buffer layer and realizing the epitaxial structure of the semiconductor device without a buffer layer. Compared with traditional epitaxial structures, the epitaxial structure of the semiconductor device provided by embodiments of the present disclosure does not require arranging a thicker buffer layer on the premise of achieving a high-quality epitaxial layer, which allows the thermal resistance to be greatly reduced and the heat generated in the epitaxial layer to be dissipated into the substrate more efficiently. At the same time, due to the elimination of the thick doped (C or Fe doped, etc.) buffer layer, the trap effect will be smaller, improving the device performance of the semiconductor device.

### BRIEF DESCRIPTION OF THE DRAWINGS

FIG. 1 is a schematic structural diagram of an epitaxial structure of a semiconductor device provided by an embodiment of the present disclosure; and

FIG. 2 is a schematic flowchart of a method of manufacturing an epitaxial structure of a semiconductor device according to an embodiment of the present disclosure.

### DETAILED DESCRIPTION

The present disclosure will be further described in detail below in conjunction with the drawings and embodiments. It can be understood that the specific embodiments described here are only used to explain the present disclosure, but not to limit the present disclosure. In addition, it should be noted that, for convenience of description, only some but not all structures related to the present disclosure are shown in the drawings.

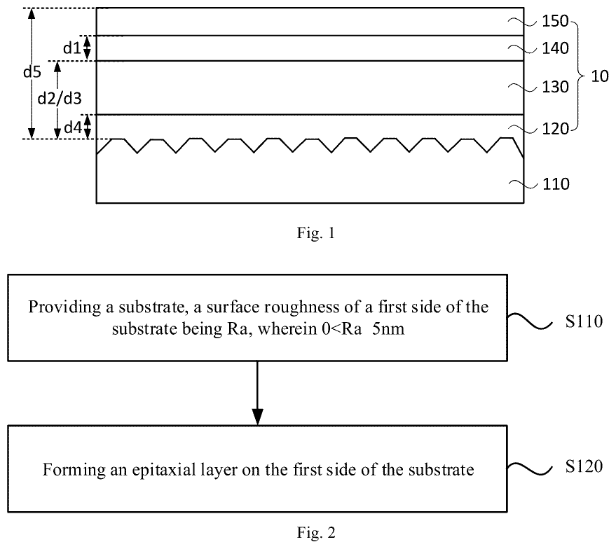

FIG. 1 is a schematic structural diagram of an epitaxial structure of a semiconductor device provided by an embodiment of the present disclosure. As shown in FIG. 1, the epitaxial structure of a semiconductor device provided by an embodiment of the present disclosure may include:
a substrate 110; and
an epitaxial layer 10 located on one side of the substrate 110;
wherein, a surface roughness of one side the substrate 110 close to the epitaxial layer 10 is Ra, wherein 0<Ra≤5 nm.

The inventor found through research that when the substrate 110 is used as the substrate for epitaxial growth, the epitaxial growth is highly dependent on the substrate 110, wherein the microscopic surface concave and convex arrangement of the substrate 110 may introduce atomic level steps on the surface of the substrate 110, during the epitaxial process, the adsorbed atoms tend to nucleate and grow at the steps, ensuring that the epitaxial process proceeds in a step flow mode, therefore, the surface roughness on the substrate 110 is one of the important factors affecting the quality of the nucleation layer.

In this embodiment, by setting the surface roughness Ra on one side of the substrate 110 close to the epitaxial layer 10 to satisfy 0<Ra≤5 nm, a high-quality epitaxial layer with fewer dislocations and defects may be epitaxially grown on the substrate 110, so there is no need to form a buffer layer, and the epitaxial structure of a semiconductor device without a buffer layer is realized.

Therein, semi-insulating silicon carbide (SiC) has high thermal conductivity and high resistivity. In the present disclosure, the silicon carbide substrate 110 is selected as the substrate material, which may be suitable for semiconductor devices for high-frequency and high-power applications, at the same time, the process of epitaxial growth on the silicon carbide substrate 110 is relatively mature and can be easily mass-produced. The following description is based on the assumption that the substrate material is silicon carbide.

It should be noted that traditional epitaxial structures require the growth of a thicker (500-2000 nm) and intentionally doped (C, Fe, etc.) buffer layer to achieve high resistance, while the thermal resistance of a thicker buffer layer is higher, which will prevent the heat generated in the epitaxial layer from dissipating into the substrate, thereby greatly affecting the operating performance of the semiconductor device.

Compared with the traditional epitaxial structure, the epitaxial structure of the semiconductor device provided by the embodiment of the present disclosure does not need to arrange a buffer layer with a large thickness on the premise of realizing a high-quality epitaxial layer 10, which allows the thermal resistance to be greatly reduced, and the heat generated in the epitaxial layer 10 can be dissipated into the silicon carbide substrate 110 more efficiently. At the same time, due to the elimination of the thick doped (C or Fe doped, etc.) buffer layer, the trap effect will be smaller, helping to improve the device performance of the semiconductor device.

It should be noted that the surface roughness Ra refers to the average value of the absolute value of the difference between the average height of the surface of the substrate 110 and the height of each single point. The surface roughness Ra may be obtained by scanning a three-dimensional topography image of the surface of the substrate 110 with an Atomic Force Microscope (AFM), and calculating the average roughness based on the three-dimensional topography image, but is not limited to this.

To sum up, in the epitaxial structure of the semiconductor device provided by the embodiment of the present disclosure, by setting the surface roughness Ra on one side of the epitaxial growth of the substrate 110 to satisfy 0<Ra≤5 nm, a high-quality epitaxial layer 10 with fewer dislocations and defects may be epitaxially grown on the substrate 110, so there is no need to form a buffer layer, and the epitaxial structure of a semiconductor device without a buffer layer is realized. Compared with the traditional epitaxial structure, the epitaxial structure of the semiconductor device provided by the embodiment of the present disclosure does not need to arrange a buffer layer with a large thickness on the premise of realizing a high-quality epitaxial layer 10, which allows the thermal resistance to be greatly reduced, and the heat generated in the epitaxial layer 10 can be dissipated into the substrate 110 more efficiently. At the same time, due to the elimination of the thick doped (C or Fe doped, etc.) buffer layer, the trap effect will be smaller, which improves the device performance of the semiconductor device.

Further, 0.2 nm≤Ra≤1 nm.

Therein, the inventor further studied and found that when the epitaxial layer 10 is grown on the substrate 110, when the surface of the silicon carbide substrate 110 is particularly smooth, for example, when the surface roughness Ra is less than 0.2 nm or even close to 0, the crystal quality of the epitaxial layer 10 will deteriorate, when the surface roughness Ra of the silicon carbide substrate 110 is greater than 1 nm or even close to 5 nm, the crystal quality of the epitaxial layer 10 will also deteriorate, or even the crystal quality will drop sharply. However, when the surface roughness Ra of the silicon carbide substrate 110 is in the range of 0.2 nm to 1 nm, it is more beneficial to the growth of the epitaxial layer 10 and the optimal crystal quality may be obtained.

Furthermore, 1 nm<Ra≤5 nm.

Therein, the inventor furthermore found that after the substrate 110 is treated at a high temperature of 1200° C. or above, the surface of the substrate 110 will be reconstructed. At the time, the quality of the epitaxial crystal grown on the surface of the substrate 110 will become better, and because the Ra value is larger at this time, it is equivalent to increasing the surface area of the substrate 110, that is, a larger heat dissipation area is obtained, so the corresponding heat dissipation at the time will be better than that of epitaxy when 0.2 nm≤Ra≤1 nm.

To sum up, when 0.2 nm≤Ra≤1 nm, epitaxy with optimal crystal quality and good heat dissipation can be obtained, when 1 nm<Ra≤5 nm, by performing high-temperature treatment on the substrate 110, an epitaxy with crystal quality within an acceptable range and optimal heat dissipation can be obtained.

In this embodiment, by further setting the surface roughness Ra on one side of the epitaxial growth of the substrate 110 to satisfy 0.2≤Ra≤5 nm, an epitaxial layer 10 with better crystal quality or better heat dissipation can be obtained.

Continuing referring to FIG. 1, the epitaxial layer 10 may include a nucleation layer 120 located on one side of the substrate 110 and a channel layer 130 located on one side of the nucleation layer 120 away from the substrate 110, and materials of the nucleation layer 120 and the channel layer 130 are both nitrides.

Therein, by setting the surface roughness Ra on one side of the substrate 110 close to the epitaxial layer 10 to satisfy 0<Ra≤5 nm, a high-quality nitride nucleation layer 120 with fewer dislocations and defects may be epitaxially grown on the substrate 110, and the high-quality nucleation layer 120 may effectively act as a back barrier, improving carrier confinement in high-frequency applications.

Further, by continuing growing on the high-quality nucleation layer 120, a high-quality nitride channel layer 130 with low defect density may be directly grown, so it is no longer necessary to form a buffer layer on the nucleation layer 120 to obtain a high-quality channel layer 130, thereby realizing an epitaxial structure of a semiconductor device without a buffer layer.

Compared with the traditional epitaxial structure, the epitaxial structure of the semiconductor device provided by the embodiment of the present disclosure does not need to arrange a buffer layer with a large thickness on the premise of realizing a high-quality channel layer 130, which allows the thermal resistance to be greatly reduced, and the heat generated in the channel layer 130 can be dissipated into the substrate 110 more efficiently. At the same time, due to the elimination of the thick doped (C or Fe doped, etc.) buffer layer, the trap effect will be smaller, helping to improve the device performance of the semiconductor device.

Therein, the specific materials of the nucleation layer 120 and the channel layer 130 may be set according to actual needs. For example, the material of the nucleation layer 120 is aluminum nitride (AlN), and the material of the channel layer 130 is gallium nitride (GaN), which is not particularly limited in this embodiment of the present disclosure.

Continuing referring to FIG. 1, the epitaxial layer 10 may further include a barrier layer 140, and the barrier layer 140 is located on one side of the channel layer 130 away from the substrate 110. A thickness of the barrier layer 140 is d1, and a distance between a surface of one side of the channel layer 130 away from the substrate 110 and a surface of one side of the substrate 110 close to the nucleation layer 120 is d2, wherein 3*d1≤d2≤30*d1. The selection of the substrate 110 may eliminate the need for a thick doped (C or Fe doped, etc.) buffer layer, and the distance d2 between the surface of one side of the channel layer 130 away from the substrate 110 and the surface of one side of the substrate 110 close to the channel layer 130 may be sharply reduced, which may satisfy d2≤18*d1 to thin the epitaxial layer as much as possible and reduce costs.

Therein, the channel layer 130 and the barrier layer 140 form a semiconductor heterojunction structure. The thickness of the nitride layer in the traditional epitaxial structure (especially the thickness of nitride between the substrate and the barrier layer) is at least 30 times greater than the thickness of the barrier layer. In this embodiment, by limiting the surface roughness Ra on one side of the epitaxial growth of the substrate 110 within a reasonable range, a high-quality nucleation layer 120 and a high-quality channel layer 130 may be directly epitaxially grown on the substrate 110, so that, while ensuring the crystal quality of the channel layer 130, there is no need to form a buffer layer on the nucleation layer 120, and the thickness of the nitride layer may be effectively reduced, and thus, the distance d2 between the surface of one side of the channel layer 130 away from the substrate 110 and the surface of one side of the substrate 110 close to the channel layer 130 is reduced to within 3 to 30 times the thickness of the barrier layer 140, which allows the heat generated in the channel layer 130 to be dissipated into the substrate 110 more effectively, greatly reducing the thermal resistance of the material.

Continuing referring to FIG. 1, a carrier layer (not shown in the drawing) may be formed in the epitaxial layer 10, by setting the surface roughness Ra on one side of the substrate 110 close to the epitaxial layer 10 to satisfy 0<Ra≤5 nm, the distance d3 between the carrier layer and the substrate 110 may be much smaller than the traditional distance while maintaining good performance, wherein 80 nm≤d3≤600 nm.

Therein, as mentioned above, the channel layer 130 and the barrier layer 140 form a semiconductor heterojunction structure. A carrier layer formed by carriers that can only move in two dimensions, Two Dimensional Electron Gas (2DEG), is formed at the interface between the barrier layer 140 and the channel layer 130, and the channel layer 130 is used to provide a channel for movement of Two Dimensional Electron Gas.

In this embodiment, by limiting the surface roughness Ra on one side of the epitaxial growth of the substrate 110 within a reasonable range, the epitaxial structure of the semiconductor device without a buffer layer may be realized while ensuring the epitaxial quality and performance, thereby effectively reducing the thickness of the nitride layer, and thus the distance d3 between the carrier layer and the substrate 110 is greatly reduced to less than 600 nm, which can effectively improve heat dissipation and reduce thermal resistance. The distance d3 between the carrier layer and the substrate 110 may be set to 80 nm to 600 nm, so that while ensuring better epitaxial layer quality, the heat generated in the channel layer 130 can be more effectively dissipated into the substrate 110, which significantly reduces the thermal resistance of the material.

It should be noted that due to the elimination of the buffer layer, the distance d3 between the carrier layer and the substrate 110 may be effectively reduced, and may be specifically set according to actual needs, for example, may be, d3≤400 nm, may be more, d3≤200 nm, thereby further reducing the thermal resistance of the material, so that the heat generated in the channel layer 130 can be dissipated into the silicon carbide substrate 110 more effectively.

It can be understood that generally the nucleation layer and the buffer layer have different functions. The nucleation layer affects the crystal quality, surface morphology, electrical properties, and other parameters of the upper heterojunction material, and mainly plays the role of matching the substrate material and the semiconductor material layer in the heterojunction structure. The buffer layer serves to bond the layer of semiconductor material that needs to be grown next. In the embodiment of the present application, the nucleation layer 120 has the functions of improving the crystal quality of the channel layer in the heterojunction and bonding the channel layer at the same time.

Continuing referring to FIG. 1, the thickness of the nucleation layer 120 may be d4, wherein 5 nm≤d4≤100 nm.

Therein, the nucleation layer 120 plays a role in bonding the channel layer 130 that needs to be grown next.

In this embodiment, by limiting the surface roughness Ra of the silicon carbide substrate 110 to satisfy 0<Ra≤5 nm, a high-quality nucleation layer 120 with fewer dislocations and defects may be epitaxially grown on the silicon carbide substrate 110, since the crystal quality of the nucleation layer 120 is relatively high, a high-quality channel layer 130 can be grown without a large thickness.

Therefore, in this embodiment, the thickness d4 of the nucleation layer 120 may be reduced to the range of 5 nm to 100 nm, while the thickness of the nucleation layer in the traditional epitaxial structure is about 200 nm, since the thermal conductivity of the nucleation layer 120 is lower than that of the channel layer 130 and the silicon carbide substrate 110, by reducing the thickness of the nucleation layer 120, the thermal resistance of the material may be effectively reduced, so that the heat generated in the channel layer 130 can be dissipated into the silicon carbide substrate 110 more effectively.

Therein, the specific thickness of the nucleation layer 120 may be set according to actual needs to obtain a more optimal nucleation layer 120. For example, the thickness d3 of the nucleation layer 120 may be further set to satisfy 5 nm≤d4≤20 nm, to further reduce the thickness of the nucleation layer 120 while ensuring the growth of the high-quality channel layer 130, thereby further reducing the thermal resistance of the material.

In order to obtain the optimal nucleation layer 120 and channel layer 130, the thickness d4 of the nucleation layer 120 may be 20 nm.

It should be noted that the specific value of the surface roughness Ra of the silicon carbide substrate 110 may be set according to actual needs, as long as the surface roughness Ra satisfies 0<Ra≤5 nm, a high-quality nucleation layer 120 may be obtained, thereby controlling the thickness of the nucleation layer 120 within a thin range.

Continuing referring to FIG. 1, the thickness of the epitaxial layer 10 may be d5, wherein d5≤1500 nm.

Therein, total thickness of a traditional epitaxial structure is usually around 3000 nm. However, in this embodiment, by setting the surface roughness Ra on one side of the epitaxial growth of the substrate 110 to satisfy (<Ra≤5 nm, while ensuring the epitaxial quality and performance, achieving high-quality nucleation layer 120 and high-quality channel layer 130, the setting of the buffer layer can be reduced, and the thickness of the nucleation layer 120 can be reduced, and the thickness d5 of the epitaxial layer 10 can be reduced to less than 1500 nm, thereby reducing raw material consumption, significantly shortening the deposition time, and minimizing manufacturing costs and increasing Metal-organic Chemical Vapor Deposition (MOCVD) production capacity. At the same time, the nitride thickness between the substrate 110 and the barrier layer 140 is reduced, which greatly reduces the thermal resistance of the material, so that the heat generated in the channel layer 130 can be dissipated into the silicon carbide substrate 110 more effectively. When 300 nm≤d5≤1200 nm is satisfied, compared with traditional epitaxial structures, not only will the quality of the channel layer material and device performance not be affected, the material will even be better than traditional materials at the device level.

The surface crystal orientation of the silicon carbide substrate 110 may be {0001}, an angle at which surface orientation of the silicon carbide substrate 110 deviates from a normal crystal orientation is a, wherein −0.25°<α<0.25°, or an angle of the surface orientation of the silicon carbide substrate 110 deviating toward a <1120> direction is β, wherein 3.5°−0.5°≤β≤3.5°+0.5°, or 4°−0.5°≤β≤4°+0.5°, or 8°−0.5°≤β≤8°+0.5°.

Therein, in order to achieve the growth of the nucleation layer 120 with higher quality, a silicon surface is selected as the growth surface of the silicon carbide substrate 110. Further, the silicon carbide substrate 110 is a normal crystal orientation, 3.5° deviating to the <1120> direction, 4° deviating to the <1120> direction, or 8° deviating to the <1120> direction, and those skilled in the art may make selections according to actual needs.

Further, in order to reduce the difficulty of production, a certain error may be allowed, for example, when the normal crystal orientation is used, the surface orientation of the silicon carbide substrate 110 is allowed to deviate by a maximum of 0.25°, that is, the surface orientation range of the silicon carbide substrate 110 is within 0+0.25°. In the same way, when the surface orientation is monotectic orientation, the wafer surface normal line of the silicon carbide substrate 110 may be set to deviate from the <1120> direction by 3.5°+0.5°, 4°+0.5° or 8°+0.5° along the main positioning edge direction, and those skilled in the art may set it according to actual needs.

Continuing referring to FIG. 1, the epitaxial layer 10 may further include a cap layer 150, and the cap layer 150 is located on one side of the barrier layer 140 away from the silicon carbide substrate 110.

Therein, the cap layer 150 is used to passivate the surface of the barrier layer 140, reduce the gate current and make the metal/semiconductor ohmic contact easier. The cap layer 150 may be made of any material that can achieve the above functions, such as gallium nitride (GaN), and the thickness of the cap layer 150 may be between 1 nm and 10 nm, and those skilled in the art can set it according to actual needs.

It should be noted that those skilled in the art may set the materials and thicknesses of respective layers in the epitaxial structure according to actual needs.

For example, the channel layer 130 may be made of gallium nitride (GaN), and its thickness may be between 100 nm and 500 nm. The thickness of the channel layer 130 may be set to 250 nm, but is not limited thereto.

For another example, the barrier layer 140 may be made of aluminum gallium nitride (AlGaN), and its thickness may be between 10 nm and 50 nm, but is not limited thereto.

Based on the same inventive concept, embodiments of the present disclosure further provide a semiconductor device, which includes the epitaxial structure of the semiconductor device according to any embodiment of the present disclosure. Therefore, the semiconductor device provided by the embodiment of the present disclosure has the technical effects of the technical solution in any of the above embodiments, and the explanation of the structures and terms that are the same as or corresponding to the above embodiments will not be repeated here.

The semiconductor device provided by the embodiment of the present disclosure may be a gallium nitride (GaN) High Electron Mobility Transistor (HEMT), and it has the characteristics such as high current density, high power density, good high-frequency characteristics, and high temperature resistance, but it is not limited to this.

It should be noted that the semiconductor device may further include other functional structures, and those skilled in the art can set them according to actual needs.

For example, the semiconductor device provided by the embodiment of the present disclosure further includes a gate, a source, and a drain. The gate, source, and drain are all located on one side of the cap layer away from the silicon carbide substrate, and the gate is located between the source and the drain.

Therein, the materials of the source and drain may include one or more metals such as nickel (Ni), titanium (Ti), aluminum (Al), gold (Au), etc., and the material of the gate may be one or more metals such as nickel (Ni), platinum (Pt), lead (Pb), gold (Au), etc.

In other embodiments, the cap layer may not be provided, and the gate, source, and drain may be directly provided on one side of the barrier layer away from the silicon carbide substrate, which is not limited in the embodiments of the present disclosure.

Based on the same inventive concept, embodiments of the present disclosure further provide a method of manufacturing an epitaxial structure of a semiconductor device, for manufacturing any epitaxial structure of a semiconductor device according to the above embodiments, and the explanation of the structures and terms that are the same as or corresponding to the above embodiments will not be repeated here. FIG. 2 is a schematic flowchart of a method of manufacturing an epitaxial structure of a semiconductor device according to an embodiment of the present disclosure. As shown in FIG. 2, the method includes:

S110. Providing a substrate, a surface roughness of a first side of the substrate being Ra, wherein 0<Ra≤5 nm.

Exemplarily, the material of the substrate is silicon carbide, after the crystal orientation of the silicon carbide substrate is determined, double-sided polishing is performed, and the surface on its first side (e.g., the silicon (Si) surface) is finely polished so that its surface roughness Ra satisfies 0<Ra≤5 nm in all diameter ranges.

The surface roughness Ra may be controlled to be 0.2≤Ra≤1 nm.

S120. Forming an epitaxial layer on the first side of the substrate.

Exemplarily, epitaxial growth may be performed within a MOCVD apparatus to form an epitaxial layer on the first side of the silicon carbide substrate. The epitaxial layer includes a nucleation layer located on one side of the silicon carbide substrate as well as a channel layer located on one side of the nucleation layer away from the silicon carbide substrate.

Therein, by setting the surface roughness Ra of the first side of the silicon carbide substrate to satisfy 0<Ra≤5 nm, a high-quality nucleation layer with fewer dislocations and defects may be epitaxially grown on a silicon carbide substrate, the high-quality nucleation layer may effectively act as a back barrier, improving carrier confinement in high-frequency applications. At the same time, by continuing to grow above the high-quality nucleation layer, a high-quality channel layer with low defect density may be directly obtained without the need to form a buffer layer on the nucleation layer, which enables the epitaxial structure of a semiconductor device without a buffer layer. Compared with traditional epitaxial structures, the method of manufacturing an epitaxial structure of a semiconductor device provided by embodiments of the present disclosure can achieve a high-quality channel layer without the need to form a buffer layer with a large thickness, in the epitaxial structure of the manufactured semiconductor device, the thermal resistance is greatly reduced, and the heat generated in the channel layer can be more effectively dissipated into the silicon carbide substrate, which helps to improve the performance of the semiconductor device.

In order to more clearly explain the method of manufacturing an epitaxial structure of a semiconductor device provided by the embodiment of the present disclosure, the method of manufacturing an epitaxial structure of a semiconductor device will be described in detail below in a feasible implementation manner.

### Embodiment 1

The method of manufacturing an epitaxial structure of a semiconductor device provided in Embodiment 1 of the present disclosure includes:

1. Providing a silicon carbide substrate.

Therein, the surface crystal orientation of the silicon carbide substrate is {0001}, the surface orientation is the normal crystal orientation, and may deviate for 0+0.25°, and both sides are polished. The silicon (Si) surface is mask-polished using Chemical Mechanical Polishing (CMP) technology, and the surface roughness Ra reaches 0.35+0.05 nm.

2. Performing epitaxial growth in an MOCVD apparatus,
wherein this may specifically include:

Raising the temperature to 1050 to 1200° C. in an H2 environment, and performing high-temperature treatment on the silicon carbide substrate for 10 to 20 minutes.

Growing an aluminum nitride nucleation layer with a thickness of 5 to 200 nm on the silicon carbide substrate, wherein the growth surface is a silicon surface.

Growing an undoped gallium nitride (i-GaN) channel layer with a thickness of 200 to 500 nm directly on the aluminum nitride nucleation layer.

Growing an aluminum gallium nitride (AlGaN) barrier layer with a thickness of 10 to 50 nm above the gallium nitride channel layer.

Growing a gallium nitride (GaN) cap layer with a thickness of 1 to 10 nm above the aluminum gallium nitride barrier layer.

The method of manufacturing an epitaxial structure of a semiconductor device will be described in detail below in another feasible implementation manner.

### Embodiment 2

The method of manufacturing an epitaxial structure of a semiconductor device provided in Embodiment 2 of the present disclosure includes:

1. Providing a silicon carbide substrate.

Therein, the surface crystal orientation of the silicon carbide substrate is {0001}, the surface orientation is monotectic orientation) (3.5°+0.25°, and both sides are polished. The silicon (Si) surface is mask-polished using Chemical Mechanical Polishing (CMP) technology, and the surface roughness Ra reaches 0.35+0.05 nm.

2. Performing epitaxial growth in an MOCVD apparatus, wherein this may specifically include:

Raising the temperature to 1050 to 1200° C. in an H2 environment, and performing high-temperature treatment on the silicon carbide substrate for 10 to 20 minutes.

Growing an aluminum nitride nucleation layer with a thickness of 5 to 200 nm on the silicon carbide substrate, wherein the growth surface is a silicon surface.

Growing an undoped gallium nitride (i-GaN) channel layer with a thickness of 200 to 500 nm directly on the aluminum nitride nucleation layer.

Growing an aluminum gallium nitride (AlGaN) barrier layer with a thickness of 10 to 50 nm above the gallium nitride channel layer.

Growing a gallium nitride (GaN) cap layer with a thickness of 1 to 10 nm above the aluminum gallium nitride barrier layer.

The method of manufacturing an epitaxial structure of a semiconductor device will be described in detail below in another feasible implementation manner.

### Embodiment 3

The method of manufacturing an epitaxial structure of a semiconductor device provided in Embodiment 3 of the present disclosure includes:

1. Providing a silicon carbide substrate.

Therein, the surface crystal orientation of the silicon carbide substrate is {0001}, the surface orientation is the normal crystal orientation, and may deviate for 0+0.25°, and both sides are polished. The silicon (Si) surface is mask-polished using Chemical Mechanical Polishing (CMP) technology, and the surface roughness Ra reaches 2+0.05 nm.

2. Performing epitaxial growth in an MOCVD apparatus, wherein this may specifically include:

Raising the temperature to 1200 to 1500° C. in an H2 environment, and performing higher high-temperature treatment on the silicon carbide substrate for 10 to 20 minutes.

Growing an aluminum nitride nucleation layer with a thickness of 5 to 200 nm on the silicon carbide substrate, wherein the growth surface is a silicon surface.

Growing a gallium nitride channel layer with a thickness of 200 to 500 nm directly on the aluminum nitride nucleation layer.

Growing an aluminum gallium nitride (AlGaN) barrier layer with a thickness of 10 to 50 nm above the gallium nitride channel layer.

Growing a gallium nitride (GaN) cap layer with a thickness of 1 to 10 nm above the aluminum gallium nitride barrier layer.

Note that the above are only the example embodiments of the present disclosure and the technical principles used. Those skilled in the art will understand that the present disclosure is not limited to the specific embodiments described herein, and those skilled in the art can make various obvious changes, rearrangements, mutual combinations, and substitutions without departing from the scope of the present disclosure. Therefore, although the present disclosure has been described in detail through the above embodiments, the present disclosure is not limited to the above embodiments, without departing from the concept of the disclosure, it may also include more other equivalent embodiments, and the scope of the disclosure is determined by the scope of the appended claims.

1. An epitaxial structure of a semiconductor device comprising:
a substrate; and
an epitaxial layer located on one side of the substrate;
wherein the epitaxial layer comprises a nucleation layer located on one side of the substrate;
wherein a surface roughness of the substrate in contact with the nucleation layer is Ra, and wherein 0<Ra≤5 nm.

2. The epitaxial structure of the semiconductor device according to claim 1, wherein 0.2 nm≤Ra≤5 nm.

3. The epitaxial structure of a semiconductor device according to claim 1,
wherein the epitaxial layer comprises a channel layer located on one side of the nucleation layer opposite the substrate; and
wherein materials of the nucleation layer and the channel layer are both nitrides.

4. The epitaxial structure of the semiconductor device according to claim 3,
wherein the epitaxial layer further comprises a barrier layer, wherein the barrier layer is located on one side of the channel layer opposite the substrate; and
wherein a thickness of the barrier layer is d1, wherein a distance between a surface of one side of the channel layer opposite the substrate and a surface of one side of the substrate close to the nucleation layer is d2, and wherein 3*d1≤d2≤30*d1.

5. The epitaxial structure of the semiconductor device according to claim 1,
wherein a carrier layer is formed in the epitaxial layer, wherein a distance between the carrier layer and the substrate is d3, and wherein d3≤600 nm.

6. The epitaxial structure of the semiconductor device according to claim 1,
wherein a thickness of the nucleation layer is d4, and wherein 5 nm≤d4≤100 nm.

7. The epitaxial structure of the semiconductor device according to claim 1, wherein
wherein a thickness of the epitaxial layer is d5, and wherein d5≤1500 nm.

8. The epitaxial structure of the semiconductor device according to claim 1, wherein
wherein a surface crystal orientation of the substrate is {0001}:
wherein an angle at which surface orientation of the substrate deviates from a normal crystal orientation is α, and wherein −0.25°≤α≤0.25°;
or
wherein an angle of the surface orientation of the substrate toward a <1120> direction is β, and wherein 3.5°−0.5°<β≤3.5°+0.5°, or 4°−0.5°≤β≤4°+0.5°, or 8°−0.5°≤β≤8°+0.5°.

9. A semiconductor device comprising the epitaxial structure of the semiconductor device according to claim 1.

10. A method of manufacturing an epitaxial structure of a semiconductor device, for manufacturing the epitaxial structure of the semiconductor device according to claim 1, the method comprising:
providing a substrate, wherein a surface roughness of a first side of the substrate is Ra, and wherein 0<Ra≤5 nm; and
forming an epitaxial layer on the first side of the substrate.

11. The epitaxial structure of the semiconductor device according to claim 4, wherein d2≤18*d1.
